(19) United States
(12) Patent Application Publication
(10) Pub. No.: US 2013/0193967 A1
(43) Pub. Date: Aug. 1, 2013

(54) METHOD FOR TAKING DATA FROM A RESONANCE FORCE MICROSCOPY PROBE

(71) Applicant: Doran Smith, Rockville, MD (US)

(72) Inventor: Doran Smith, Rockville, MD (US)

(21) Appl. No.: 13/362,149

(22) Filed: Jan. 31, 2012

(51) Int. Cl. G01R 33/48; G01R 33/34

(52) U.S. Cl. 324/309; 324/318

(57) ABSTRACT

A control apparatus for extracting data from an MRFM system in accordance with exemplary embodiments of the present invention comprising a visualization controller for controlling operation of the MRFM system, an initialization module, coupled to the visualization controller, for retrieving initialization data from a data source, a data collection module, coupled to the visualization controller, for extracting data from the MRFM system and an imaging module for generating image data based on the extracted data.

### GOVERNMENT INTEREST

The invention described herein may be manufactured, used and licensed by or for the U.S. Government.

### FIELD OF INVENTION

Embodiments of the present invention generally relate to imaging sensing software and, more particularly, to a method for taking data from resonance force microscopy probe.

### BACKGROUND OF THE INVENTION

Magnetic resonance force microscopy (MRFM) is an imaging technique that acquires magnetic resonance images (MRI) at nanometer scales, and possibly at atomic scales in the future. An MRFM system comprises a probe, method of applying a background magnetic field, electronics, and optics. The system measures variations in a resonant frequency of a cantilever or variations in the amplitude of an oscillating cantilever. The changes in the characteristic of the cantilever being monitored are indicative of the tomography of the sample. More specifically, as depicted in FIG. 1, an MRFM probe 100 comprises a base 102 with a cantilever 104 tipped with a magnetic (for example, iron cobalt) particle 106 to resonate as the spin of the electrons or nuclei in the sample 101 are reversed. There is a background magnetic field 108 generated by a background magnetic field generator 110 which creates a uniform background magnetic field in the sample 101. As the magnetic tip 106 moves close to the sample 101, the atoms' electrons or nuclear spins become attracted (force detection) to the tip and generate a small force on the cantilever 104. Using a radio frequency (RF) magnetic field applied by an RF antenna 117 through the RF source 105, the spins are then repeatedly flipped at the cantilever's resonant frequency, causing the cantilever 104 to oscillate at its resonant frequency. In the geometry shown, when the cantilever 104 oscillates, the magnetic particle's 106 magnetic moment remains parallel to the background magnetic field 108, and thus it experiences no torque. The displacement of the cantilever is measured with an optical sensor 114 comprised of an interferometer (laser beam) 116 and an optical fiber 118 to create a series of 2-D images of the sample 101 held by sample stage 120, which are combined to generate a 3-D image. The interferometer measures the time dependent displacement of the cantilever 104. Software then extracts from the time dependent displacement the cantilever's frequency. The current hardware designs of MRFM probes are not suited for taking data from arbitrarily sized samples and thus the software that controls the probes is not suited for imaging arbitrarily sized samples.

Therefore, there is a need in the art for an apparatus and method for extracting data from an MRFM probe in a more accurate and efficient manner from arbitrarily sized samples.

### BRIEF SUMMARY OF THE INVENTION

Embodiments of the present invention relate to a control apparatus for extracting data from an MRFM system in accordance with exemplary embodiments of the present invention comprising a visualization controller for controlling operation of the MRFM system; an initialization module, coupled to the visualization controller, for retrieving initialization data from a data source; a data collection module, coupled to the visualization controller, for extracting data from the MRFM system; and an imaging module for generating image data based on the extracted data.

Embodiments of the present invention relate to a computer implemented method for extracting data from an MRFM system comprising retrieving initialization data from a data source; extracting data from the MRFM system; and generating image data based on the extracted data.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a conventional MRFM system known to those of ordinary skill in the art;

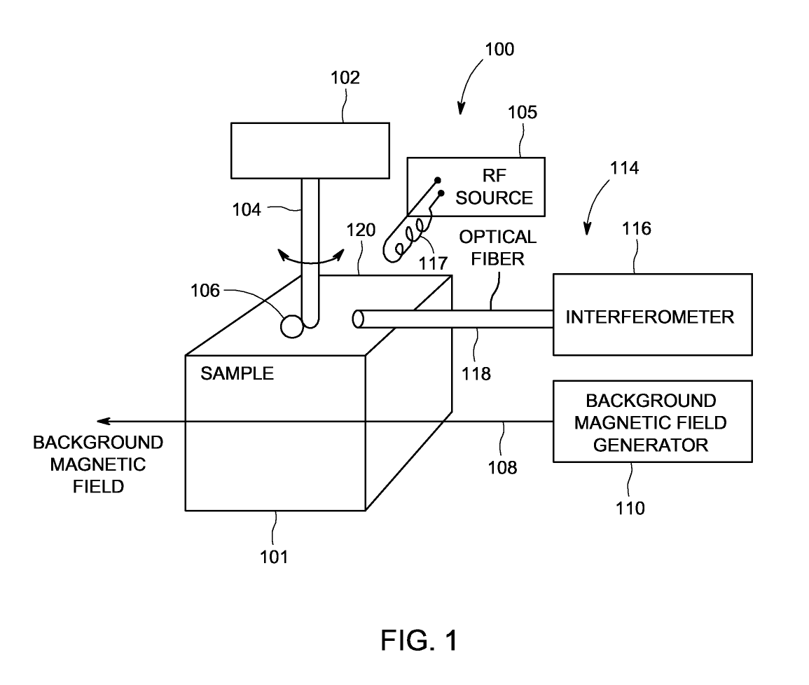

FIG. 2 depicts a block diagram of an MRFM system in accordance with an exemplary embodiment of the present invention;

FIG. 3 is a block diagram of a visualization device for extracting data from an MRFM system in accordance with exemplary embodiments of the present invention;

FIG. 4 is a block diagram depicting an exemplary embodiment of a computer system in accordance with exemplary embodiments of the present invention;

FIG. 5 is a flow diagram of a method for extracting data from an MRFM probe in accordance with exemplary embodiments of the present invention; and

FIG. 6 is a flow diagram of a method for performing computation on the extracted data in accordance with exemplary embodiments of the present invention.

### DETAILED DESCRIPTION OF THE INVENTION

Embodiments of the present invention comprise software modules for controlling and operating an MRFM system and extracting data from that system including the frequency oscillation values for the magnetic sensor in the MRFM system. The software modules perform computations on this extracted data to assemble graphical and statistical plots as well as to perform imaging of the sample particle structure. The software modules also store the extracted data in a database for future experimental use. Embodiments of the software module also enable adjustment of the background magnetic field as well as the pulsing of RF signals by the RF antenna and the delay following the pulsing.

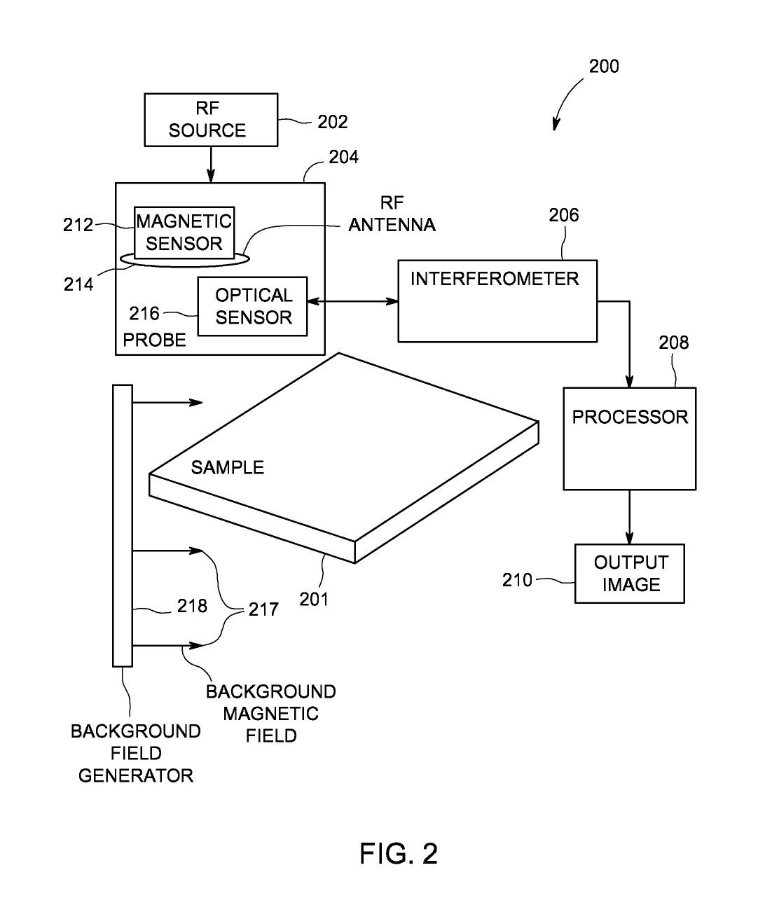

FIG. 2 depicts a block diagram of an MRFM system 200 in accordance with an exemplary embodiment of the present invention. The system 200 generally has an RF source 202 coupled to a RF antenna 214 which is part of the probe 204. The probe 204 comprises an interferometer 206 for performing optical measurements on the displacement of the magnetic sensor 212 using the optical sensor 216 in the probe 204 of sample 201. The interferometer 206 transmits the measurements to processor 208. Processor 208 generates an output image 210 based on the measurements or oscillations of portions of the probe 204. The probe 204 comprises a magnetic sensor 212, an RF antenna 214 and an optical sensor 216. The apparatus 200 is kept in a spatially homogeneous background magnetic field 217 (approximately 9 T) generated by a background magnetic field generator 218. In an exemplary embodiment, the background magnetic field generator 218 comprises a superconducting magnet. In an exemplary embodiment, the magnetic sensor 212 is comprised of a silicon cantilever on which is attached a smaller magnetic particle 219 (for example, a Samarium Cobalt, or, SmCo particle 10 μm in diameter) which generates a spatially inhomogeneous field. The magnetic field experienced at a particular point in the sample 201 is the sum of the background magnetic field 217 and the magnetic field generated by the magnetic particle 219. The RF antenna 214 at least partially circumscribes the magnetic sensor 212. The RF antenna 214 generates RF signals which cause the spin of the electrons or nuclei of the sample 201 to reverse and oppose the SmCo particle 219 on the end of the magnetic sensor 212. This repeated reversal of the spin of the particles in sample 201 causes the magnetic sensor 212 to oscillate at a particular frequency. The interferometer 206 senses oscillation of the magnetic sensor 212 using optical sensor 216 by using optical fiber 217 to reflect a laser off of the magnetic sensor 212. In another exemplary embodiment, the sample 201 is directly coupled to the bridge comprising the magnetic sensor 212 and an SmCo particle attached to the magnetic sensor 212. According to an exemplary embodiment, the optical fiber 113 is 125 microns in diameter and is within about a 1/10 of a millimeter of the cantilever. In an exemplary embodiment, the optical sensor 216 is an optical fiber approximately twenty five times greater in diameter than the width of the bridge of the magnetic sensor 212. The gap between the optical fiber and the magnetic sensor 212 is fixed at a particular distance in this embodiment.

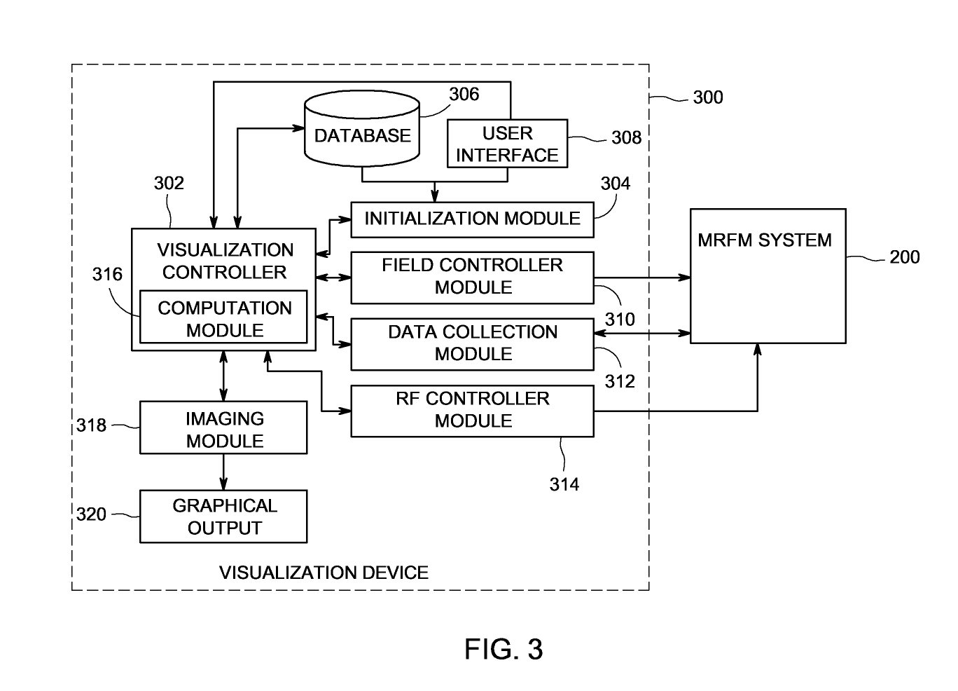

FIG. 3 is a block diagram of a visualization device 300 for extracting data from the MRFM system 200 in accordance with exemplary embodiments of the present invention. The visualization device 300 comprises a visualization controller 302 for controlling operation of the apparatus 300. The visualization controller 302 determines when the software is initialized, when data is collected from the MRFM system 200, and for modifying components of the MRFM system 200. The visualization controller 302 also performs data processing on data collected from the MRFM system 200 and creates graphical plots representing various operations on the data. In an exemplary embodiment, the visualization device 300 is collocated with the MRFM system 200. In another exemplary embodiment, the visualization device 300 is located remotely and commands and data are transmitted between the visualization device 300 and the MRFM system 200 through a network. A user interacts with the visualization device 300 through user interface 308. In the user interface 308, a user can define parameters for data collection, real-time analysis and storage parameters including the set of parameters describing the state of the instrument during data collection, the amount of data collected, and how much preprocessing was performed on the data before storage using graphical programming software, for example, LabVIEW® subroutine virtual instruments (Vis).

The visualization controller 302 couples with the initialization module 304 to retrieve the initialization data entered by the user and also to retrieve data to initialize the electronic instrumentation that comprises the MRFM system 200 from the database 306. After initialization, the visualization controller 302 invokes the data collection module 312. The visualization controller 302 also controls the RF controller module 314 which triggers a radio frequency (RF) pulse along with a delay after each pulse at various intervals. The sample 201 is hit with the RF pulse to change the spin of nuclei in the sample particles, changing the sample 201 magnetic properties, thus changing the resonant frequency of the magnetic sensor in the MRFM system 200. The data collection module 312 is directly coupled to the MRFM system 200 so as to collect magnetic field data which the computation module 316 will later convert to cantilever frequency data vs. time at each of a set of magnetic field (B-Field) points throughout the sample 201. The changes in the cantilever frequency, from before to after the RF is applied to the sample, is used to determine the number of electron or nuclear spins in the sample at each B-field point. The data collection module 312 extracts the frequency of the magnetic sensor 212 from the magnetic sensor 212 displacements as measured by the interferometer 206 at the request of the visualization controller and transmits this data to the computation module 316. In exemplary embodiments, the visualization controller 302 also stores data collection parameters, raw experimental data from data collection module 312, experiment date, experiment time, MRFM system 200 calibration values, and other data needed for post-hoc analysis and repetition of the experiment, in storage database 306.

The computation module 316 calculates a mean magnetic sensor frequency value before an RF pulse (a first frequency), and a mean magnetic sensor frequency after an RF pulse (second frequency) and computes the difference between the two frequencies. The computation module 316 finds the mean difference between the frequency values as measured at each point in the B-field and stores these in database 306. Based on the collected frequency values and mean frequency values, a graphical output 320 is produced by the imaging module 318. The graphical output 320 comprises statistical graphs and images of the structure of the particles in sample 201. In other exemplary embodiments, the visualization controller 302 controls the field controller module 312 which incremeptally modifies the background magnetic field that the MRFM system is exposed to.

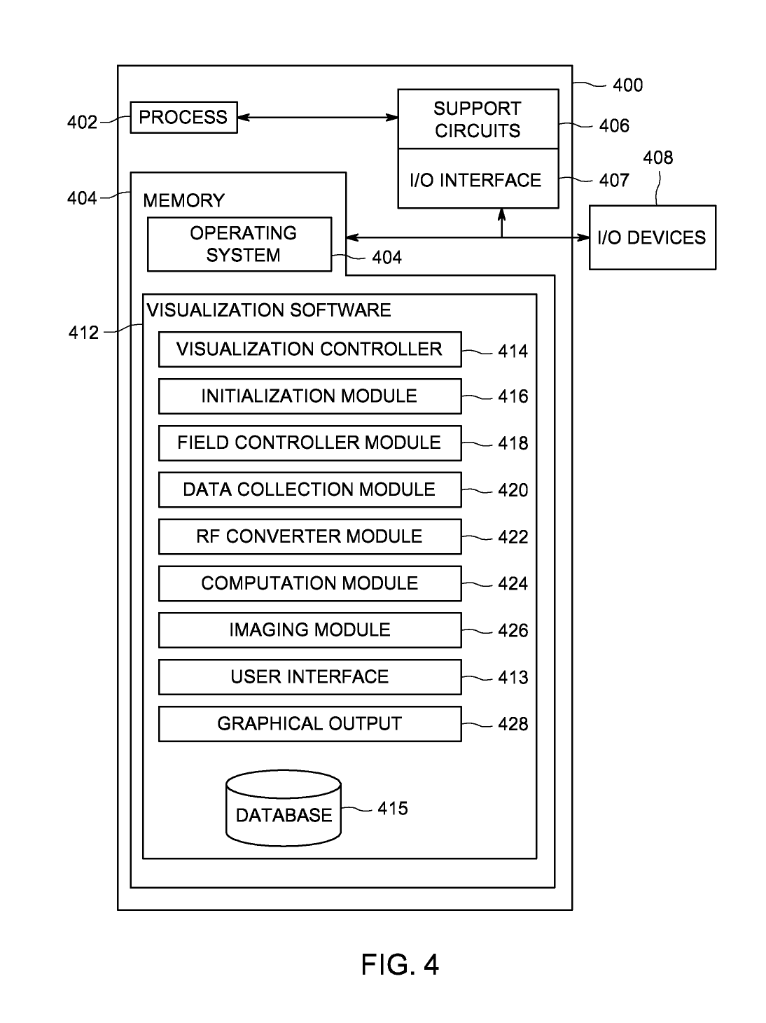

FIG. 4 is a block diagram depicting an exemplary embodiment of a computer system 400 in accordance with exemplary embodiments of the present invention. The computer system 400 is used to implement at least a portion of the apparatus 300, namely the visualization controller 302, the initialization module 304, the field controller module 310, the data collection module 312, the RF controller module 314, the computation module 316, the imaging module 318, the user interface 308, the database 306 and the graphical output 320. The computer system 400 includes a processor 402, a memory 404 and various support circuits 406. The processor 402 may include one or more microprocessors known in the art, and/or dedicated function processors such as field programmable gate arrays programmed to perform dedicated processing functions. The support circuits 406 for the processor 402 include microcontrollers, application specific integrated circuits (ASIC), cache, power supplies, clock circuits, data registers, I/O interface 407, and the like. The I/O interface 407 may be directly coupled to the memory 404 or coupled through the supporting circuits 406. The I/O interface 407 may also be configured for communication with input devices and/or output devices 408, such as, network devices, various storage devices, mouse, keyboard, displays, sensors and the like.

The memory 404 stores non-transient processor-executable instructions and/or data that may be executed by and/or used by the processor 402. These processor-executable instructions may comprise firmware, software, and the like, or some combination thereof. Modules having processor-executable instructions that are stored in the memory 204 comprise visualization software 412. According to an exemplary embodiment of the present invention, the visualization software 412 comprises a visualization controller 414, an initialization module 416, a field controller module 418, a data collection module 420, an RF controller module 422, a computation module 424, an imaging module 426, a user interface 413, a database 415 and graphical output 428. The computer system 400 may be programmed with one or more operating systems (generally referred to as operating system (OS) 410), which may include OS/2, Java Virtual Machine, Linux, Solaris, Unix, HPUX, AIX, Windows, Windows95, Windows98, Windows NT, and Windows2000, WindowsME, WindowsXP, Windows Server, among other known platforms. At least a portion of the operating system 410 may be disposed in the memory 404. In an exemplary embodiment, the memory 404 may include one or more of the following: random access memory, read only memory, magneto-resistive read/write memory, optical read/write memory, cache memory, magnetic read/write memory, and the like, as well as signal-bearing media, not including non-transitory signals such as carrier waves and the like.

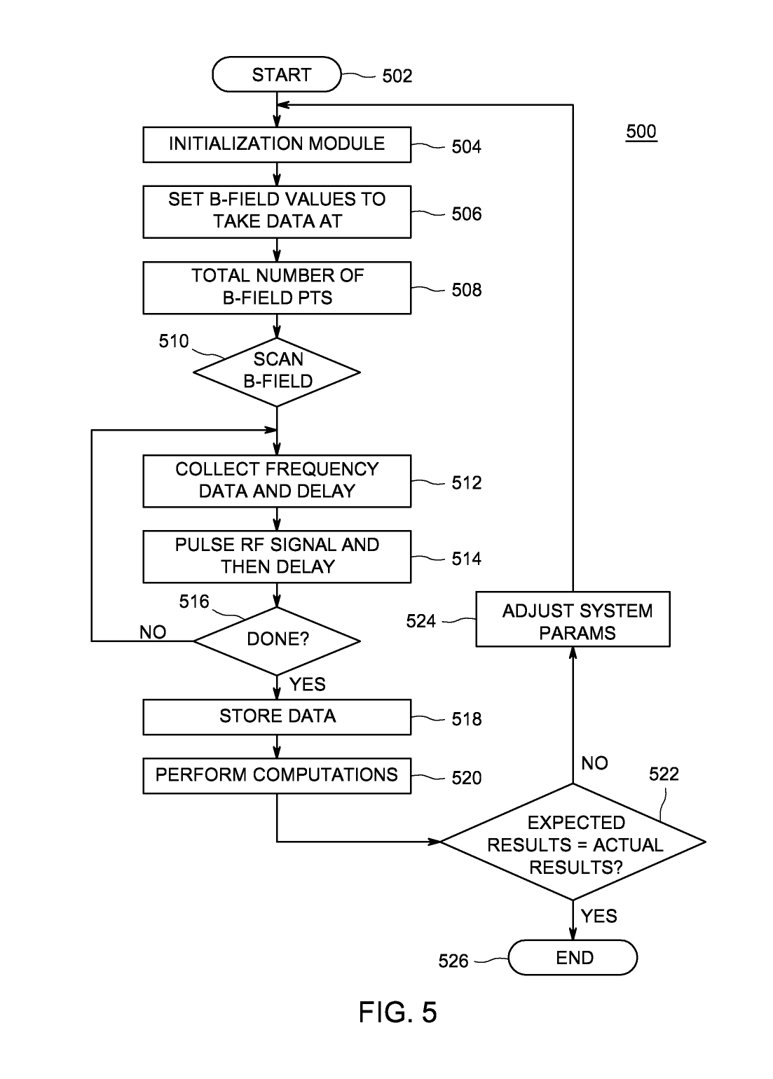

FIG. 5 is a flow diagram of a method 500 for extracting data from an MRFM probe in accordance with exemplary embodiments of the present invention. FIG. 5 represents an exemplary implementation of the method for extracting data from an MRFM probe by the visualization software 412, stored in memory 404 and executed by the processor 402. The method 500 begins at step 502 and proceeds to step 504. At step 304, the initialization module 416 collects parameters entered into the user interface 413 by a user of the system 400. At step 506, the field controller module 418 sets the background magnetic field values at which to extract data. The method then moves to step 508, where the total number of B-field points are calculated. At step 510, the B-field is scanned and the frequency data is collected by the data collection module 420 at step 512. The RF controller module 422 pulses the RF antenna 214 of the MRFM system 200 and then introduces a delay (for example, ˜1 second) at step 514. If all B-field data points have not been scanned at step 516, the method moves to step 512, iterating through each B-field point. At step 518, the frequency data is stored in the database 415 and the data is processed by the computation module 424 at step 520. At step 522, the method determines whether the actual results are equal to the expected results. If they are not, then at step 524, the MRFM system 200 parameters are adjusted accordingly, such as the magnitude of the background magnetic field, the strength of the RF signal pulses, delay, and the like, and the method returns to step 504. If actual results meet expected results, the method ends at step 526.

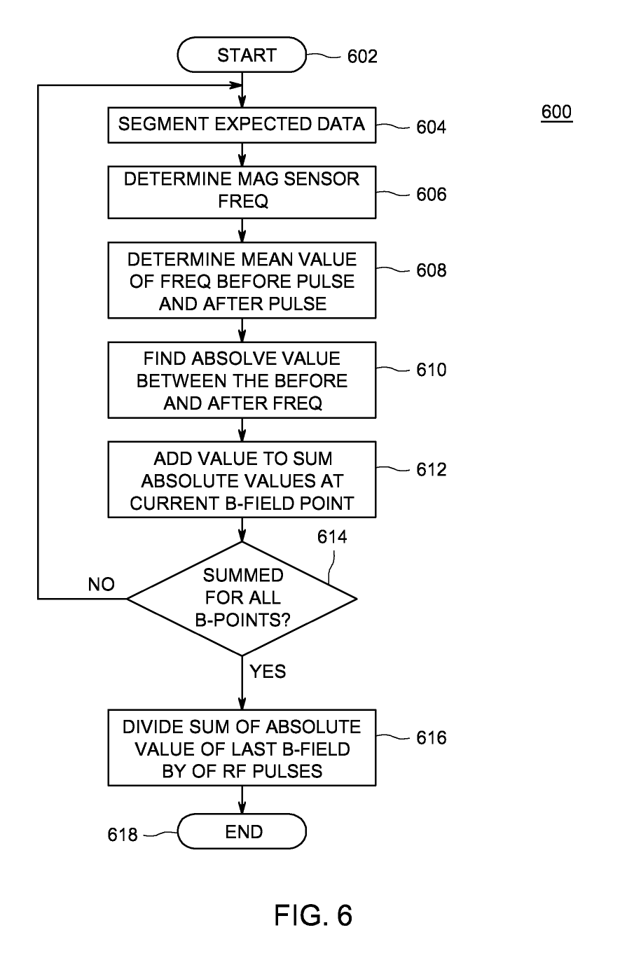

FIG. 6 is a functional diagram of a method 600 for performing computation on the extracted data from method 500 in accordance with exemplary embodiments of the present invention. In an exemplary embodiment, the method 600 starts at step 602 and segments the data into n segments at step 604. At step 606, the method determines the magnetic sensor frequency for each segment. The mean value of the magnetic sensor frequency is determined before and after each RF pulse at step 608. Then, the absolute value between the two frequencies is determined, denoting the total number of spins, at step 610. This absolute value is added to the sum of absolute values at the current B-field point in step 612. If all B-field points have not had their frequencies summed, the method returns to step 604. If it is determined at step 614 that all B-field points are summed, the sum of the absolute values at the last B-field point is divided by the number of RF pulses, giving the average change in frequency at step 616. The method ends at step 618.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the present disclosure and its practical applications, to thereby enable others skilled in the art to best utilize the invention and various embodiments with various modifications as may be suited to the particular use contemplated.

Various elements, devices, modules and circuits are described above in associated with their respective functions. These elements, devices, modules and circuits are considered means for performing their respective functions as described herein. While the foregoing is directed to embodiments of the present invention, other and further embodiments of the invention may be devised without departing from the basic scope thereof, and the scope thereof is determined by the claims that follow.

1. A control apparatus for extracting data from a magnetic resonance force microscopy (MRFM) system in accordance with exemplary embodiments of the present invention comprising:
a visualization controller for controlling operation of the MRFM system;
an initialization module, coupled to the visualization controller, for retrieving initialization data from a data source;
a data collection module, coupled to the visualization controller, for extracting data from the MRFM system; and
an imaging module for generating image data based on the extracted data.

2. The apparatus of claim 1 further comprising:
a field controller module, coupled to the visualization controller, for adjusting background magnetic field in the MRFM system; and
a radio-frequency (RF) controller module, coupled to the visualization controller, for pulsing an RF signal and introducing a delay between the pulsed RF signal produced by an RF antenna in the MRFM system;

3. The apparatus of claim 1 wherein the visualization controller comprises a computation module for performing computations on the extracted data.

4. The apparatus of claim 1 wherein a user of the control apparatus inputs initialization parameters to the initialization module.

5. The apparatus of claim 3 wherein the extracted data is a plurality of frequencies each at a different magnetic field point of a magnetic sensor of the MRFM system before and after the pulsed RF signal.

6. The apparatus of claim 5 wherein the visualization controller segments the frequency data into a plurality of segments, averages the frequencies in each segment from the plurality of segments before and after the pulsed RF signal producing a first average and a second average, computing the absolute value difference between the first average and second average and summing with previously computed absolute values for each magnetic field point in a sample of the MRFM system to produce a delta-frequency sum, and dividing the delta-frequency sum by a number of total RF pulses created by the RF controller module.

7. A computer implemented method for extracting data from a magnetic resonance force microscopy (MRFM) system in accordance with exemplary embodiments of the present invention comprising:
retrieving initialization data from a data source;
extracting data from the MRFM system; and
generating image data based on the extracted data.

8. The method of claim 1 further comprising:
adjusting background magnetic field in the MRFM system; and
pulsing a radio-frequency (RF) signal and introducing a delay between the pulsed RF signal produced by an RF antenna in the MRFM system;

9. The method of claim 1 further comprising performing computations on the extracted data.

10. The method of claim 1 wherein initialization data is retrieved from a user's input.

11. The method of claim 9 wherein the extracted data is a plurality of frequencies each at a different magnetic field point of a magnetic sensor of the MRFM system before and after the pulsed RF signal.

12. The method of claim 11 further comprising segmenting the frequency data into a plurality of segments, averaging the frequencies in each segment from the plurality of segments before and after the pulsed RF signal producing a first average and a second average, computing the absolute value difference between the first average and second average and summing with previously computed absolute values for each magnetic field point in a sample of the MRFM system to produce a delta-frequency sum, and dividing the delta-frequency sum by a number of total RF pulses created by the RF controller module.
